(19) United States
(12) Patent Application Publication
(10) Pub. No.: US 2012/0153487 A1
(43) Pub. Date: Jun. 21, 2012

(54) SUBSTRATE FOR ELECTRON-BEAM DRAWING

(75) Inventor: Keiichiro Yusu, Kanagawa (JP)

(73) Assignee: KABUSHIKI KAISHA TOSHIBA, Tokyo (JP)

(21) Appl. No.: 13/407,909

(22) Filed: Feb. 29, 2012

Related U.S. Application Data
(63) Continuation of application No. PCT/JP2009/065212, filed on Aug. 31, 2009.

(51) Int. Cl. H01L 29/43

(52) U.S. Cl. 257/769; 257/741; 257/E29.139

(57) ABSTRACT

A substrate for electron-beam drawing, characterized by including a base layer 20, a first layer 30 formed on the base layer 20 comprising one of Y, Zr, Nb, Mo, Tc, Ru, Rh, Pd, Ag, In, Sn, Sb, La, Ce, Pr, Nd, Pm, Sm, Hf, Re, Os, Ir, Pt, Au, Pb, and Bi, a second layer 40 formed on the first layer 30 comprising one of C and B and having a film-thickness of 100 μm to 300 μm, and a resist layer 50 formed above the second layer 40.

### CROSS-REFERENCE TO THE RELATED APPLICATION(S)

This is a Continuation Application of PCT Application No. PCT/JP2009/065212, filed on Aug. 31, 2009, which is published under PCT Article 21 (2) in Japanese, the entire contents of which are incorporated herein by reference.

### FIELD

Embodiments described herein generally relate to a substrate for electron-beam drawing (also called substrate).

### BACKGROUND

In a mask manufacturing step in a semiconductor process, fine line formation has hitherto been performed by electron beam drawing. Recently, the introduction of electron beam drawing techniques has been studied as a countermeasure for greatly increasing the capacity of optical recording media and magnetic recording media. The electron beam drawing techniques are used in the process of manufacturing master discs serving as originals when the mass duplication of the recording media is implemented. Fine patterns are manufactured by irradiating electron beams on each master disc on which an electron sensitive material called a “resist” is applied.

When fine patterns are manufactured, the fine patterns can be formed by increasing an accelerating voltage for accelerating electron beams. However, the electron beams' penetration capability of penetrating a resist is enhanced. Thus, after penetrating the resist, electrons are scattered in a substrate and reflected to and reirradiated onto the resist. This phenomenon is referred to as backscattering, which hinders the formation of fine patterns close to each other.

### BRIEF DESCRIPTION OF THE DRAWINGS

A general configuration that implements the various features of the present invention will be described with reference to the drawings. The drawings and the associated descriptions are provided to illustrate embodiments of the invention and not to limit the scope of the invention.

FIG. 1 is a schematic cross-sectional diagram of a substrate 10 according to a first embodiment of the invention.

FIG. 2 is a table illustrating an electron mean free path of a material configuring a second layer 40 of the substrate 10.

FIG. 3 is a diagram illustrating a substrate 15 according to a second embodiment of the invention.

FIG. 4 is a diagram of a substrate according to the second embodiment of the invention.

FIG. 5 illustrates results of observing, with AFM, a substrate 10 manufactured according to Example 1, after dried.

FIG. 6 illustrates results of observing, with AFM, a substrate 10 manufactured according to Example 2, after dried.

FIG. 7 illustrates results of observing, with AFM, a substrate 10 manufactured according to Example 3, after dried.

FIG. 8 illustrates results of observing, with AFM, a substrate 10 manufactured according to Comparative Example 1, after dried.

FIG. 9 illustrates results of observing, with AFM, a substrate 10 manufactured according to Comparative Example 2, after dried.

### DETAILED DESCRIPTION

According to the embodiments described herein, there is provided a substrate for electron-beam drawing according to the invention is characterized by comprising a base layer, a first layer formed on the base layer to contain one of Y, Zr, Nb, Mo, Tc, Ru, Rh, Pd, Ag, In, Sn, Sb, La, Ce, Pr, Nd, Pm, Sm, Hf, Re, Os, Ir, Pt, Au, Pb, and Bi, a second layer formed on the first layer comprising one of C and B and to have a film-thickness of 100 μm to 300 μm, and a resist layer formed above the second layer.

According to the substrate (also called the substrate for electron-beam drawing) thus configured, fine patterns can be formed, which can suppress the backscattering of electron beams to the resist layer from the base layer and form fine patterns close to each other.

Embodiments according to the present invention will be described in detail with reference to the accompanying drawings. The scope of the claimed invention should not be limited to the examples illustrated in the drawings and those described in below. In the drawings described hereinafter, components corresponding to each other in reference numeral represent similar ones. Thus, the redundant description of such components is omitted.

### First Embodiment

A substrate 10 according to a first embodiment of the invention is described below.

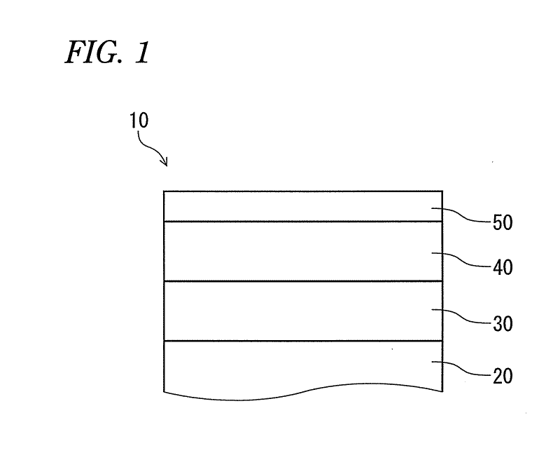

FIG. 1 is a diagram illustrating the substrate 10 according to the present embodiment.

The substrate 10 according to the present embodiment includes a base layer 20, a first layer 30 formed on the base layer 20, a second layer 40 formed on the first layer 30, and a resist layer 50 formed on the second layer 20.

For example, a widely used substrate, such as a Si substrate, is preferably used for the base layer 20.

A material easily forming an interface in a film is preferably used for the first layer 30.

The film-thickness of the first layer 30 is preferably equal to or more than 100 nm and equal to or less than 200 nm.

Preferably, a material thicker than the length of the electron mean free path of a material forming the first layer 30 is preferable for that of the second layer 40.

Incidentally, the film-thickness of the second layer 40 can be made by providing the first layer 30 to be thinner than the length of the electron mean free path of the material configuring the second layer 40. This will be described below.

The mean free path represents the average value of a distance at which electron scattering can progress without being hindered. The mean free path □ can be obtained from the following expression (1).

$$λ = \frac{5.54 \cdot {10}^{- 2} V A}{ρ {Z}^{\frac{1}{3}} ( Z + 1 )} \qquad ( 1 )$$

In this expression (1), V represents an incident electron accelerating voltage, A designates an average atomic weight, Z denotes an average atomic number, and ρ represents a density.

In the case of a compound AₓB₁₋ₓ (x ranges from 0 to 1) composed of elements A and B, the average atomic weight Z, of the compound AₓB₁₋ₓ can be expressed as follows.

Zₐᵥ=Z_{A}·x+Z_{B}·(1−x) (2)

In this expression (2), Z_{A} represents the atomic weight of the element A, and Z_{B} represents that of the element B.

Similarly, the average atomic number Aₐᵥ can be expressed as follows.

Aₐᵥ=A_{A}·x+A_{B}·(1−x) (3)

In this expression (3), A_{A} represents the atomic number of the element A, and A_{B} represents that of the element B. Similarly, in a case where a compound is composed of three or more elements, the average atomic weight of the compound can be obtained by summing up the atomic weight of each element, which is multiplied by a content rate thereof.

Preferably, e.g., inorganic materials, such as carbon (C), and boron (B), and various organic polymers containing C, O, H, N, and Si are used as the material of the second layer 40. In the case of using these materials, preferably, the film-thickness of the second layer 40 is equal to or more than 100 μm and equal to or less than 300 μm.

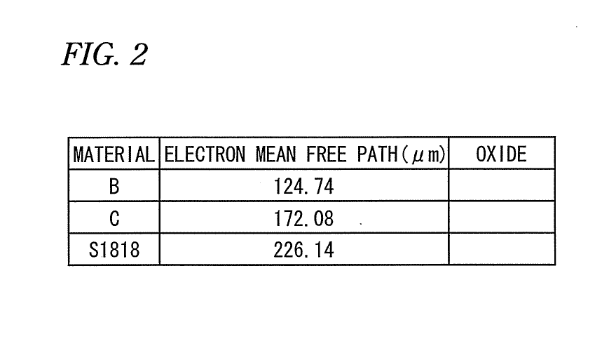

FIG. 2 illustrates a result of calculation of the electron mean free path of each material configuring the second layer 40. Incidentally, S1818 illustrated in FIG. 2 is a photosensitive resist material, which is listed as an example of the organic polymer. Because S1818 is composed of C, O, H, N, and S, the electron mean free path of S1818 is calculated from the average atomic weight and the average atomic number of each of these atoms. In addition, the calculation illustrated in FIG. 2 is performed by assuming the accelerating voltage V as 50 kV.

As illustrated in FIG. 2, the mean free path of carbon is 172.08 μm. Thus, if the film-thickness of the second layer 40 is set to be equal to or more than 172 μm, an electron beam is theoretically considered to converge in the second layer 40. However, although an electron beam can be converged to some extent in the second layer, generally, defects are generated in a film due to stacking and distortion, so that the electron beam is scattered due to the defects and reaches the first layer 30. Accordingly, it is difficult to appropriately converge an electron beam in the second layer 40.

On the other hand, if the film-thickness of the second layer 40 is set to be equal to or less than 172 μm, an electron beam is scattered in the second layer 40, as described above. In addition, because the film-thickness of the second layer 40 is smaller than the mean free path of materials configuring the second layer 40, the electron beam reaches the first layer 30.

That is, it is necessary to converge electron beams in the first layer 30.

Preferably, the material of the first layer 30 is one of Y, Zr, Nb, Mo, Tc, Ru, Rh, Pd, Ag, In , Sn, Sb, La, Ce, Pr, Nd, Pm, Sm, Hf, Re, Os, Ir, Pt, Au, Pb, and Bi, which can forma grain boundary in the first layer 30 to form an interface. These materials easily form grain boundaries by being partially oxidized. Especially, Mo, Ag, and Bi are respectively oxidized to MoO₃, Ag₂O, and Bi₂O₃, so that grain boundary oxides formed by covering grain boundaries with oxides are easily formed.

Thus, when the grain boundary is formed, an electron beam incident in the first layer 30 is scattered by the grain boundary. Consequently, the electron beam can be converged in the first layer 30. Incidentally, the film-thickness of the first layer 30 is equal to or more than 100 nm and equal to or less than 200 nm.

Next, an operation principle of the substrate 10 is described hereinafter.

When an electron beam is incident upon the substrate 10, the electron beam is transmitted in the resist layer 50 while scattered. However, the resist layer 50 is composed of light elements such as C, O, H, and N. Thus, the electron beam reaches the second layer 40 without being largely scattered.

The electron beam transmitted by the resist layer 50 is transmitted by the second layer 40 and the first layer 30 in this order and reaches the base layer 20.

The electron beam reaching the inside of the first layer 30 is scattered by the grain boundary formed in the first layer 30. Thus, a fraction of the electron beam, which is converged in the first layer 30 and reflected and reirradiated onto the resist layer 50, extremely decreases. That is, the electron beam is converged to some extent by the second layer 40. Then, the electron beam is scattered by the grain boundary formed in the first layer 30 so as to be converged. Accordingly, the backscattering of the electron beam can prominently be prevented.

The substrate 10 according to the present embodiment can suppress the backscattering of an electron beam from a surface of the base layer 20 to the resist layer 50. Thus, fine patterns close to each other can be formed.

### Second Embodiment

A substrate 15 according to a second embodiment of the invention is described hereinafter.

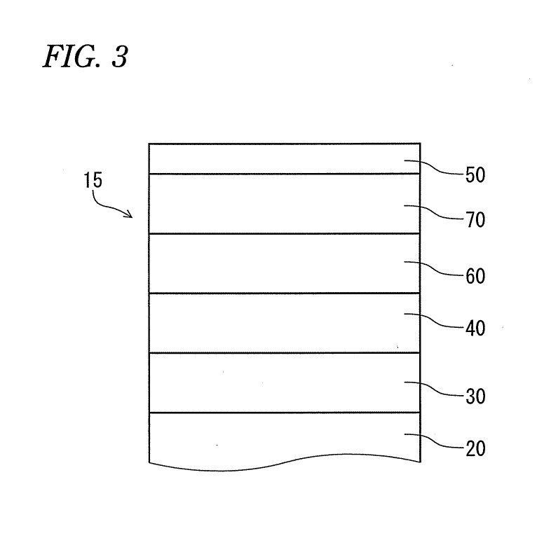

FIG. 3 is a diagram illustrating the substrate 15 according to the present embodiment.

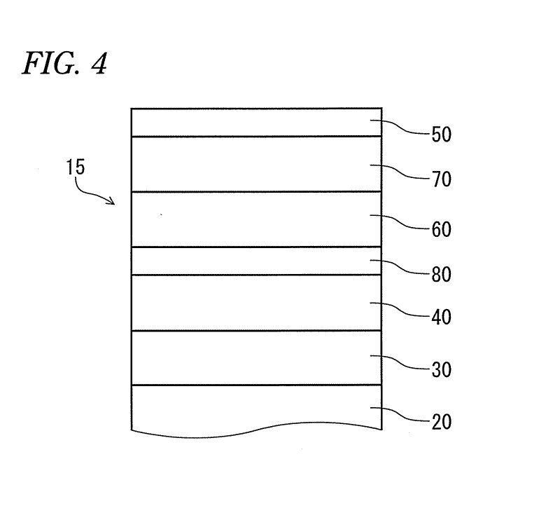

The substrate 15 includes a base layer 20, a first layer 30 formed on the base layer 20, a second layer 40 formed on the first layer 30, a third layer 60 formed on the second layer 40, a fourth layer 70 formed on the third layer 60, and a resist layer 50 formed on the fourth layer 70. As illustrated in FIG. 4, a buffer layer 80 made of SOG (spin-on-glass) for suppressing roughness of a surface of the second layer 40 can be inserted between the second layer 40 and the third layer 60.

Preferably, the material of the third layer 60 is one of Y, Zr, Nb, Mo, Tc, Ru, Rh, Pd, Ag, In , Sn, Sb, La, Ce, Pr, Nd, Pm, Sm, Hf, Re, Os, Ir, Pt, Au, Pb, and Bi, each of which can form a grain boundary in the third layer 60. These materials easily form grain boundaries by being partially oxidized. Especially, Mo, Ag, and Bi are respectively oxidized to MoO₃, Ag₂O, and Bi₂O₃, so that grain boundary oxides formed by covering grain boundaries with oxides are easily formed. The film-thickness of the third layer 60 is equal to or more than 100 nm and equal to or less than 200 nm.

Preferably, e.g., inorganic materials, such as carbon (C), and boron (B), and various organic polymers containing C, O, H, N, and the like are used as the material of the fourth layer 70. Each material, whose film-thickness is thicker than the length of the electron mean free path of the material having a film-thickness configuring that of the fourth layer 70, is preferable. As described in the description of the first embodiment, the film-thickness of the fourth layer 70 can be set to be less than the length of the electron mean free path of the materials configuring the fourth layer 70. Incidentally, the film-thickness of the fourth layer 70 is equal to or more than 100 μm and equal to or less than 300 μm.

Next, an operating principle of the substrate 15 is described hereinafter.

When an electron beam is incident upon the substrate 15, the electron beam is transmitted in the resist layer 50 while scattered. However, because the resist layer 50 is composed of light elements such as C, O, H, and N, the electron beam is not largely scattered, and reaches the fourth layer 70.

Then, the electron beam transmitted by the resist layer 50 is transmitted by the fourth layer 70, the third layer 60, the second layer 40, and the first layer 30 in this order and reaches the base layer 10. At that time, the electron beam which reaches the inside of the third layer 60 is scattered by the grain boundary formed in the third layer 60. Thus, as described above, the electron beam transmitted by the fourth layer 70 converges in the third layer 60. The fraction of the electron beam, which is converged in the third layer 60 and reflected to and reirradiated onto the resist layer 50, extremely decreases. In addition, a small fraction of the electron beam, which is also transmitted by the third layer 60, breaks into the inside of the second layer 40. The electron beam incident upon the second layer 40 reaches the inside of the first layer 30.

The electron beam reaching the inside of the first layer 30 is scattered by the grain boundary formed in the first layer 30. Thus, the fraction of the electron beam, which is converged in the first layer 30 and reflected and reirradiated onto the resist layer 50, extremely decreases.

The substrate 15 according to the present embodiment can suppress the backscattering of an electron beam towards the resist layer 50 and form fine patterns close to each other.

### First Example

A Si-substrate (the Si-substrate corresponds to the base layer 20) which is 6 inches in diameter and 0.725 mm in thickness is installed in a vacuum film formation apparatus. After the degree of vacuum in the vacuum film formation apparatus is maintained at 7×10⁻⁴ Pa, Mo-film (first layer 30) having a thickness of about 100 μm is formed thereon under Ar-gas pressure of 0.7 Pa by a DC magnetron sputtering method. Successively, a C-film (second layer 40) having a thickness of about 100 μm is formed thereon using a CVD apparatus. The Si-substrate on which the Mo-film and the C-film are formed is installed in a spin coater. An electron beam sensitive resist ZEP520 having a thickness of 70 nm is coated thereon. Thus, the substrate 10 is manufactured.

The manufactured substrate 10 is installed in an electron beam drawing apparatus. The electron beam is outwardly and radially fed at a constant feeding pitch from a position corresponding to a radius of 10 mm while rotated at a linear speed of 0.7 m/s. A track pitch is changed within a range from 70 nm to 400 nm. Electron-beam-irradiated regions formed a spiral trajectory. A pitch obtained by adding the width of an irradiated part to that of a nonirradiated part is defined as a track pitch. For example, if the width of the electron-beam-irradiated part is 50 nm and that of the nonirradiated part is 50 nm, the track pitch is 100 nm. The accelerating voltage of the electron beam is set at 50 kV. A beam extraction voltage is set at 5.0 kV. A beam electric-current is set at 30 μA. A beam diameter is set at 30 nm.

After the drawing performed with the electron beam, the substrate 10 is installed in the spin coater. Developer ZED-N50 is applied thereto by a spin coat method. The substrate 10 is left for 60 seconds as it is. In addition, a rinsing solution ZMD-B is applied to the substrate 10. Then, the substrate 10 is held 10 seconds, and spun off and dried.

The dried substrate 10 is observed by an atomic force microscope (AFM). According to the observation, an exposed part irradiated with the electronic beam is dissolved and dropped by developing. Thus, projections and recesses are formed in lines and spaces arranged at regular intervals. Accordingly, a typical positive type resist is shown.

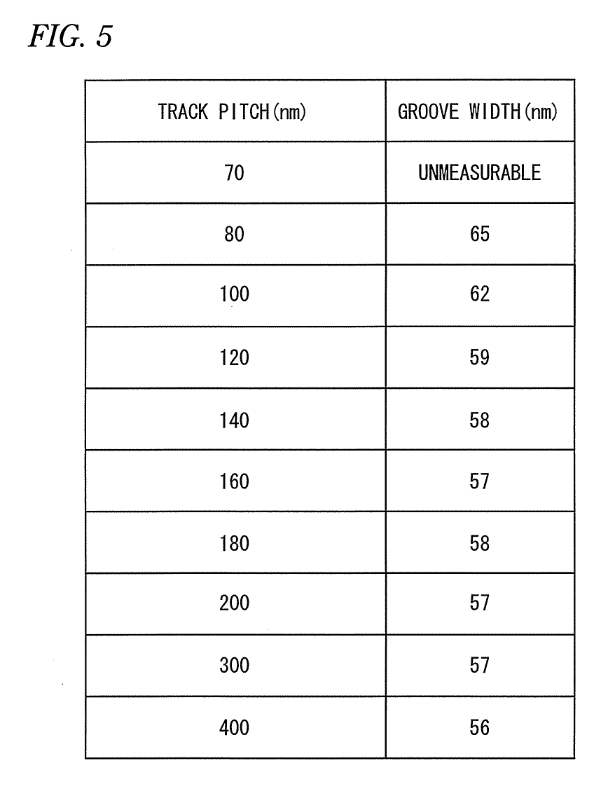

FIG. 5 illustrates results of observing, with AFM, the substrate 10 after dried. FIG. 5 illustrates each track pitch (nm), and a groove width (nm) at each track pitch.

As illustrated in FIG. 5, if the track pitch is equal to or more than 140 nm, there is little change in the groove width (which is almost constant at about 57 mm). Thus, it is found that backscattering is suppressed.

A cause for this is considered to be that the material Mo of the first layer 30 forms a grain boundary oxide, and that an electron beam is scattered by the grain boundary and converged in the first layer 30.

### Example 2

A Si-substrate (the Si-substrate corresponds to the base layer 20) which is 6 inches in diameter and 0.725 mm in thickness is installed in a vacuum film formation apparatus. After the degree of vacuum in the vacuum film formation apparatus is maintained at 7×10⁻⁴ Pa, a Ag-film (first layer 30) having a thickness of about 100 μm is formed thereon under Ar-gas pressure of 0.7 Pa by a DC magnetron sputtering method. Successively, the Si-substrate on which the first layer 30 is formed is installed in a spin coater. A polymer S1818 (second layer 40) having a thickness of about 100 μm is coated thereon. Similarly to Example 1, the resist is coated thereon. Thus, the substrate 10 is manufactured.

After that, electron beam drawing is performed on the same condition as that in Example 1. A resultant substrate is observed by AFM.

According to the observation, an exposed part irradiated with the electronic beam is dissolved and dropped by developing. Thus, projections and recesses are formed in lines and spaces arranged at regular intervals. Accordingly, a typical positive type resist is shown.

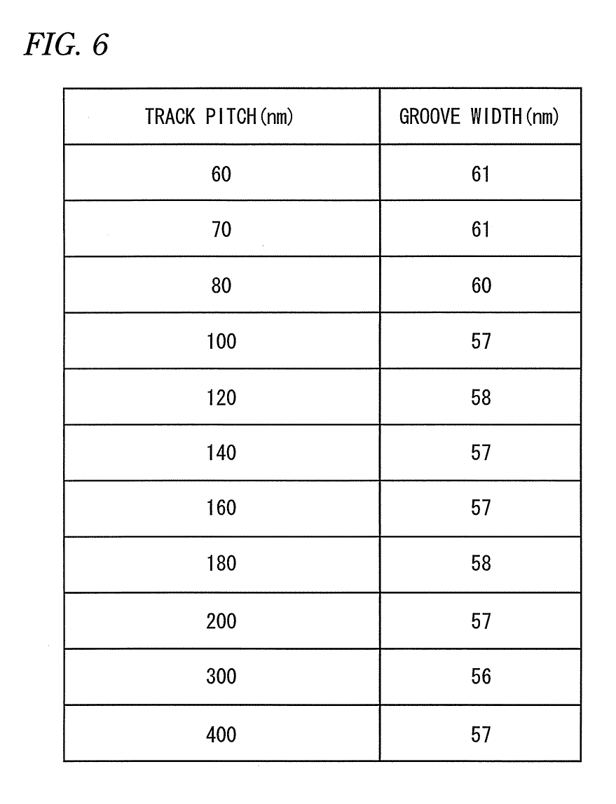

FIG. 6 illustrates results of observing, with AFM, the substrate 10 after dried. FIG. 6 illustrates each track pitch (nm), and a groove width (nm) at each track pitch.

It is seem from FIG. 6 that grooves could be formed at a track pitch to 60 nm, that if the track pitch is equal to or more than 100 nm, the pitch hardly changed (constant at about 57 nm), and that backscattering is suppressed.

A cause for this is considered to be that Ag of the first layer 30 formed a grain boundary oxide, and that an electron beam is scattered by the grain boundary and converged in the first layer 30.

### Example 3

On conditions similar to those in the case of Example 1, a Ag-film (first layer 30) having a thickness of 100 nm, and a C-film (second layer 40) having a thickness of 100 μm are formed on a Si-substrate (the Si-substrate corresponds to the base layer 20) through the buffer layer 80 such as SOG. In addition, a Bi-film (third layer 50) having a thickness of 100 nm, and a C-film (fourth layer 60) having a thickness of 100 μm are formed thereon. Then, a resist is applied thereto. Thus, a substrate 15 is manufactured, which had a structure similar to that illustrated in FIG. 3 described in the first embodiment.

After that, the manufacture substrate 15 is installed in an electron beam drawing apparatus. On conditions similar to those in the case of Example 1 except that an electron beam is rotated at a linear speed of 1.0 m/s, electron beam drawing is performed. Then, the substrate 15 is observed with AFM. As a result of the observation, it is found that an exposed part irradiated with an electron beam is dissolved and dropped, that projections and recesses are formed in lines and spaces arranged at regular intervals. Accordingly, a typical positive type resist is shown.

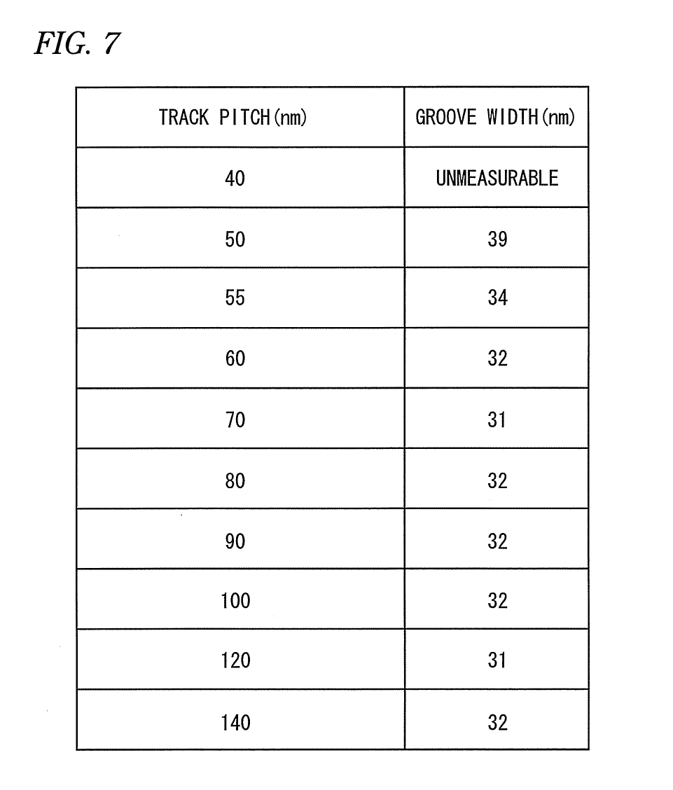

FIG. 7 illustrates results of observing, with AFM, the substrate 15 after dried. FIG. 7 illustrates each track pitch (nm), and a groove width (nm) at each track pitch.

It is seen from FIG. 7 that grooves could be formed at a track pitch of 50 nm, that if the track pitch is equal to or more than 60 nm, the pitch hardly changed (constant at about 32 nm), and that backscattering is suppressed.

A cause for this is considered to be that Ag of the first layer 30 and Bi of the third layer 50 formed grain boundary oxides, and that an electron beam is scattered by the grain boundary and converged in the first layer 30 and the third layer 50.

### Comparative Example 1

A Si-substrate which is 6 inches in diameter and 0.725 mm in thickness is installed in a spin coater. Then, an electron beam sensitive resist ZEP520 having a thickness of 70 nm is coated thereon. Thus, a substrate for comparison is manufactured. After that, on conditions similar to those in the case of Example 1, electron beam drawing is performed on the substrate for comparison. Then, the substrate for comparison is observed with AFM.

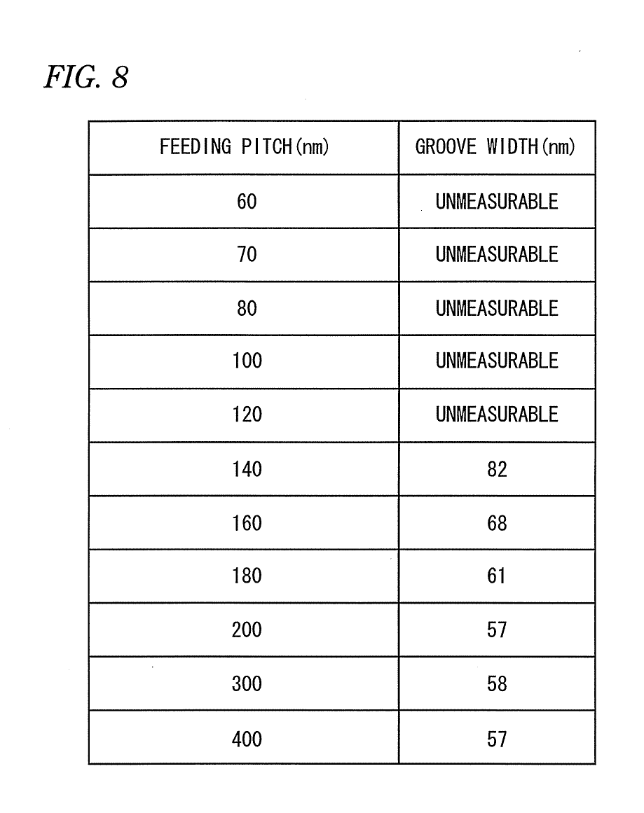

FIG. 8 illustrates results of observing, with AFM, the dried substrate for comparison. FIG. 8 illustrates each track pitch (nm) and the groove width (nm) corresponding to each track pitch.

It is found from FIG. 8 that if the track pitch is equal to or less than 120 nm, groove widths are unmeasurable, and no grooves are formed.

### Comparative Example 2

A Si-substrate which is 6 inches in diameter and 0.725 mm in thickness is installed in a spin coater. Then, an electron beam sensitive resist ZEP520 having a thickness of 70 nm is coated thereon. Thus, a substrate for comparison is manufactured. After that, on conditions similar to those in Example 1, except that the substrate for comparison is placed in an electron beam drawing apparatus, and that an electron beam is rotated at a linear speed of 1.0 m/s, electron beam drawing is performed on the substrate for comparison. Then, the substrate for comparison is observed with AFM.

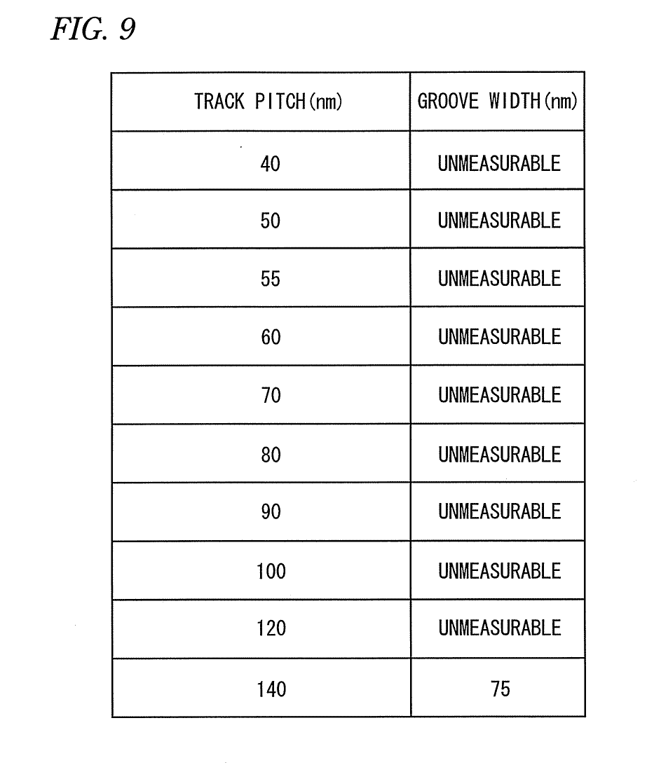

FIG. 9 illustrates results of observing, with AFM, the dried substrate for comparison. FIG. 9 illustrates each track pitch (nm) and the groove width (nm) corresponding to each track pitch.

It is found from FIG. 9 that if the track pitch is equal to or less than 120 nm, groove widths are unmeasurable, and no grooves are formed.

Although the embodiments according to the present invention have been described above, the present invention is not limited to the above-mentioned embodiments but can be variously modified. Constituent components disclosed in the aforementioned embodiments may be combined suitably to form various modifications. For example, some of all constituent components disclosed in the embodiments may be removed or may be appropriately combined.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A substrate for electron-beam drawing comprising:
a base layer;
a first layer formed on the base layer, the first layer comprising one of Y, Zr, Nb, Mo, Tc, Ru, Rh, Pd, Ag, In, Sn, Sb, La, Ce, Pr, Nd, Pm, Sm, Hf, Re, Os, Ir, Pt, Au, Pb, and Bi;
a second layer formed on the first layer, the second layer comprising one of C and B and having a film-thickness of 100 μm to 300 μm; and
a resist layer formed above the second layer.

2. The substrate according to claim 1,
wherein the first layer is comprised of Mo, Ag, or Bi.

3. The substrate according to claim 1,
wherein the second layer contains an organic polymer.

4. The substrate according to claim 1,
wherein a film-thickness of the first layer is in a range from 100 nm to 200 nm.

5. The substrate according to claim 1 further comprising:
a third layer formed between the second layer and the resist layer, the third layer comprising one of Y, Zr, Nb, Mo, Tc, Ru, Rh, Pd, Ag, In, Sn, Sb, La, Ce, Pr, Nd, Pm, Sm, Hf, Re, Os, Ir, Pt, Au, Pb, and Bi; and
a fourth layer formed on the third layer comprising one of C, B, and an organic polymer, the fourth layer having a film-thickness in a range from 100 μm to 300 μm.
